(19) United States
(12) Patent Application Publication
(10) Pub. No.: US 2010/0283107 A1
(43) Pub. Date: Nov. 11, 2010

(54) MOS Transistor With Better Short Channel Effect Control and Corresponding Manufacturing Method

(76) Inventors: Markus Muller, Brussels (BE); Alexandre Mondot, Grenoble (FR); Arnaud Pouydebasque, Gieres (FR)

Correspondence Address: Docket Clerk, P O Drawer 800889, Dallas, TX, 75380, US

(21) Appl. No.: 12/086,561

(22) PCT Filed: Dec. 7, 2006
(86) PCT No.: PCT/EP2006/011792

§ 371 Date: Jul. 19, 2010

(30) Foreign Application Priority Data
Dec. 13, 2005 (EP) 05292650.8

(51) Int. Cl. H01L 29/78; H01L 21/336

(52) U.S. Cl. 257/368; 438/275; 257/E29.255; 257/E21.409

(57) ABSTRACT

The integrated circuit comprises at least one MOS transistor (T) including a gate (GR) having a bottom part in contact with the gate oxide. Said bottom part has an inhomogeneous work function (WFB, WFA) along the length of the gate between the source and drain regions, the value of the work function being greater at the extremities of the gate than in the centre of the gate. The gate comprises a first material (A) in the centre and a second material (B) in the remaining part. Such configuration is obtained for example by silicidation.

The invention relates to the integrated circuits and more particularly to the control of Short Channel Effect (SCE) in MOS transistors.

In deep sub-micron CMOS devices, the dependence of the threshold voltage on the gate length induced by the Short Channel Effect (SCE) and the Drain Induced Barrier Lowering (DIBL) is a serious problem for manufacturing.

Industry demands require IC circuits with higher densities and thus the down-scaling of the MOS transistors. However the shrink of the MOS transistors leads to the emergence of two parasitic and well known effects, the Short Channel Effect (SCE) and the Drain Induced Barrier Lowering (DIBL) which lower the voltage threshold of the transistor with decreasing gate length. Physically they can be explained by the electrostatic influence of the S/D regions (SCE) or an applied voltage on the drain (DIBL) on the channel region in very small devices lowering the energy barrier for electrons or holes in the channel when the transistor is switched off (gate voltage zero) and leading to higher off currents.

Process induced fluctuations on the gate length are directly responsible for dispersions from the targeted threshold value and thus the desired electrical properties. Commonly, these two effects (SCE and DIBL) are minimized by the deliberate additional implantation of dopants in the channel after gate patterning under a certain angle, commonly referred to as pocket or halo implantation. The objective is to increase locally, i.e. in proximity of the gate edge, the channel doping. As a consequence the effective channel doping increases with decreasing channel length, raising the threshold voltage and thus leading to a counter effect to the SCE and DIBL. However, the needed high channel doping doses degrade the mobility in the channel and lead to lower performance values. Moreover, the pocket effect is very sensitive to the exact positioning of the dopants, which depends on many factors: on the gate shape which acts as an implantation hard mask, the presence of offset spacers, the implantation energy and angle and finally on the thermal budget of the fabrication flow and the S/D activation anneal.

A different way of compensating the SCE and DIBL consists for the gate to have an inhomogeneous work function along the length of the gate between the source and drain regions, The value of the work function being greater at the extremities of the gate than in the centre of the gate for NMOS transistors and smaller for PMOS transistors.

The man skilled in the art knows that the work function is the energy difference between the electron vacuum level and the Fermi level.

Such an inhomogeneous work function will lead to a positive shift of the threshold voltage for NMOS devices whereas for PMOS devices this shift will be negative for decreasing gate lengths. In both cases, when the gate length is reduced, this trend is opposed to the SCE and DIBL effect which helps to achieve a desired flat curve of the threshold voltage versus the gate length.

A transistor having a gate comprising several different materials displaying with such an inhomogeneous work function is disclosed for example in U.S. Pat. No. 6,586,808B1.

Transistors having gates comprising several different materials are also disclosed in U.S. Pat. No. 6,300,177B1 or in WO 00/77828A2 or in U.S. Pat. No. 6,251,760B1 or in U.S. Pat. No. 6,696,725B1.

However manufacturing such a transistor's gate requires specific method steps including specific layer deposition, which renders the manufacturing method rather complicated.

The invention intends to solve this problem.

According to an aspect of the invention it is proposed a method of manufacturing a MOS transistor comprising forming a gate having a bottom part above and in contact with a dielectric layer, for example an oxide layer, said bottom part having an inhomogeneous work function along the length of the gate between the source and drain regions; in particular the value of the work function being greater at the extremities of the gate than in the centre of the gate if said MOS transistor is a NMOS transistor and smaller at the extremities of the gate than in the centre of the gate if said MOS transistor is a PMOS transistor. The gate forming phase comprises
forming above said dielectric layer a gate region comprising a gate material, for example a semiconductor material, in particular poly-Si, amorphous silicon, GaAS, InP, or a mixture thereof,
forming insulating spacers on the lateral walls of the gate region,
forming a metal layer above said gate region,
performing a transformation process including causing said metal layer to react with said gate material and choosing the thickness of said metal layer and process points of said transformation process such that at the end of the transformation process said gate region comprises a first material within a central area located at the centre of the bottom part of the gate region and a second material in the remaining part of said gate region, said second material having a work function different than the work function of said first material, in particular greater than that of said first material if said MOS transistor is a NMOS transistor and smaller than that of said first material if said MOS transistor is a PMOS transistor.

For example at the end of the transformation process said semiconductor gate material, except the portion thereof located at the centre of the bottom part of the gate region, has been totally transformed in said second material. In other words, in such an embodiment, all the semiconductor gate material, except the portion thereof located within said central area, reacts with the metal layer during the transformation process so that said first material remains the semiconductor gate material.

The transformation process is advantageously a silicidation process. Accordingly the invention uses here a process usually used in the manufacturing of a transistor.

The semiconductor gate material may be N doped poly-silicon if said transistor is a NMOS transistor and P doped poly-silicon if said transistor is a PMOS transistor and said second material may be a midgap material in particular a metal silicide, for example NiSi.

As an example, the gate forming phase may thus comprise:
forming above said oxide layer a polysilicon gate region,
forming insulating spacers on the lateral edges of the polysilicon gate region,
performing a silicidation process of said polysilicon gate region including forming a metal layer above said polysilicon gate region and said spacers, and choosing the thickness of said metal layer and process points of thermal treatment of said silicidation process such that at the end of the silicidation process, the bottom part of the gate comprises polysilicon at the centre of the gate and metal silicide at the extremities of the gate.

This is due in particular to diffusion phenomena occurring at the edges of the gate increasing the metal amount which is available for the silicidation at the gate edges with respect to the centre, known as narrow line width effects.

The thickness of the deposited metal layer is chosen so that to avoid a full silicidation of the polysilicon gate region.

The man skilled in the art will be able to determine such a thickness depending in particular on the gate thickness (or height). As an example, when the metal is nickel, the thickness of said metal layer is advantageously smaller than the half of the thickness of the polysilicon gate region and greater than one quarter of the thickness.

However, the same result can be achieved by silicidation with other metals like cobalt, titanium, molybdenium with adjusted deposited metal thickness and process points.

Another possible solution for obtaining the inhomogeneous work function can consist in having metal poor silicide in the centre of the gate but metal rich silicide at the extremities of the gate by using the same diffusion principle as those used in the silicidation.

According to another aspect of the invention it is proposed an integrated circuit comprising at least one MOS transistor including a gate having a bottom part in contact with the gate dielectric, said bottom part having an inhomogeneous work function along the length of the gate between the source and drain regions, the value of the work function being in particular greater at the extremities of the gate than in the centre of the gate if said transistor is a NMOS transistor and smaller if said transistor is a PMOS transistor. The gate comprises a first material in a central area located at the centre of the bottom part of the gate in contact with said dielectric layer and a second material in the remaining part of the gate.

According to an embodiment of the invention, said first material is N doped poly-silicon if said transistor is a NMOS transistor and P doped poly-silicon if said transistor is a PMOS transistor and said second material is a midgap material, in particular a metal silicide, for example NiSi or CoSi₂.

Other advantages and features of the invention will appear on examining the detailed description of embodiments, these being in no way limiting, and of the appended drawings in which:

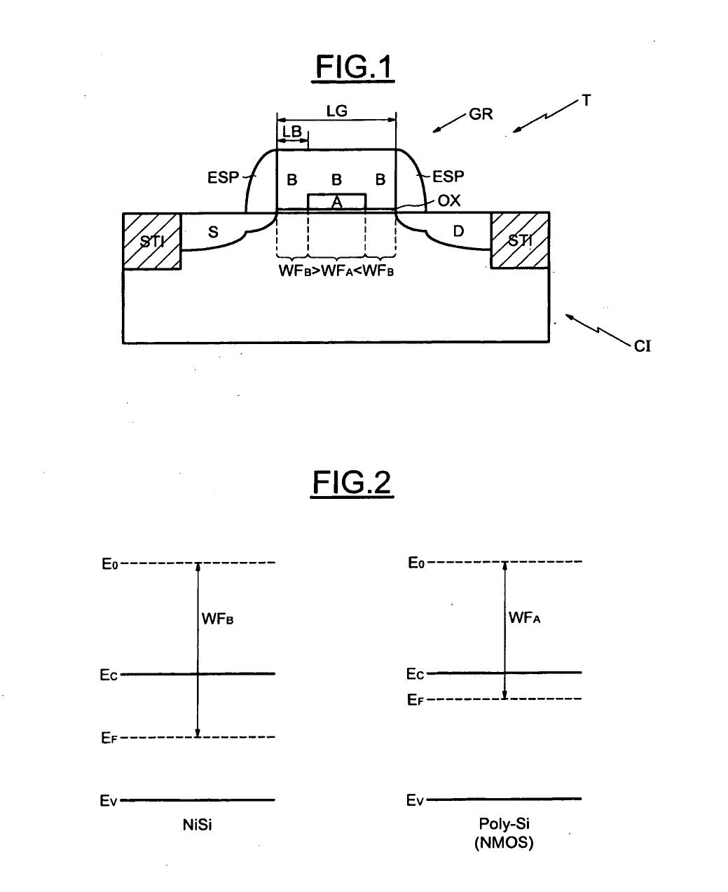

FIG. 1 illustrates diagrammatically an embodiment of a transistor belonging to an integrated circuit according to the invention,

FIG. 2 illustrates the different work functions of the gate of a transistor according to an embodiment of the invention,

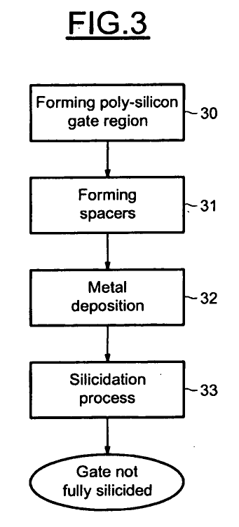

FIG. 3 illustrates diagrammatically a flow chart related to an embodiment of a method according to the invention, and

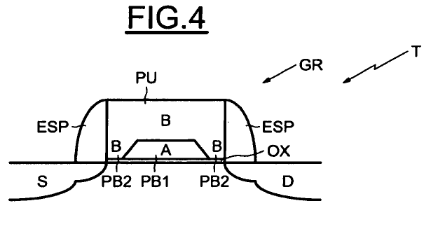

FIG. 4 illustrates diagrammatically another embodiment of a transistor belonging to an integrated circuit according to the invention.

In FIG. 1, the integrated circuit CI comprises a MOS transistor T having an active zone delimited by Shallow Trench Isolation (STI). Conventionally, the MOS transistor comprises a source region S, a drain region D and a gate GR isolated from the substrate by a gate oxide OX.

Further, insulating spacers ESP are provided on the lateral walls of the gate.

The length of the gate is referenced LG and is also the length of the channel of the transistor.

In this embodiment, the bottom part of the gate, and, in this example, the whole gate, comprises several different materials. More precisely, a first material A is located within a central area in the centre of the bottom part of the gate and a second material B is located in the remaining part of the gate, in particular at the extremities of the gate.

The length of each portion of the bottom part of the gate which is formed with the material B is referenced LB.

The gate has an inhomogeneous work function along the length LG of the gate. More precisely, if T is a NMOS (resp. PMOS) transistor, the work function of material B, referenced WF_{B} is greater (resp. smaller) than the work function of the material A, referenced WF_{A}.

In fact, what is important is that the bottom part of the gate, i.e. for example the first nanometers of the gates located above the gate oxide OX, displays an inhomogeneous work function along the source-drain direction.

As illustrated in FIG. 2 for a NMOS transistor, the work function WF_{A} is close to the energy level of the conduction band Ec of the silicon, whereas the work function WF_{B} is close to the silicon midgap. (The gap is the difference between the energy level of the conduction band and the energy level of the valence band).

As explained more in details thereafter, material A may be a doped poly-silicon, N⁺ for NMOS device and P⁺ for PMOS device, whereas material B is for example a metal silicide, as NiSi.

For a PMOS transistor, the work function WF_{A} is close to the energy level of the valence band of the silicon.

Eo is the vacuum level and Ef the Fermi level.

For very great LG with respect to 2 LB, the work function of the gate and thus the threshold voltage of the transistor is only defined by the central material A.

But, if LG gets comparable to 2 LB, the work function will gradually move to a midgap value. As a consequence, for reduced gate length, a positive shift of the threshold voltage is obtained for NMOS transistors, whereas, for PMOS transistors, these shifts will be negative. In both cases, this trend is opposed to the SCE and DIBL effects, which help to achieve a desired flat curve of the threshold voltage versus the gate length.

A first possibility to obtain a gate displaying such an inhomogeneous work function is disclosed in FIG. 3.

First of all, in step 30, a polysilicon gate region is conventionally formed above the gate oxide OX.

Then, after a first doping of the substrate to form the drain and source extension, spacers ESP are conventionally formed (step 31). A doping of the polysilicon gate region is also performed.

Then, a layer of metal is deposited (step 32) on the full wafer, i.e. in particular on the top of the doped polysilicon gate region and on the spacer ESP.

Then, silicidation process 33 is performed.

The several characteristic points of the silicidation process are chosen such that the gate obtained after the silicidation process is not fully silicided as illustrated for example in FIG. 4.

More precisely, as an example for a silicidation process using nickel as metal, the ratio between the thickness of the metal layer deposited on the doped polysilicon gate region and the height of the polysilicon region is chosen smaller than 0.5 but greater than 0.25.

Further, a first anneal around 300° C. is performed. The exact duration of the first anneal, typically between one to few minutes, depends on the gate height and the desired width LB. For example, for a width LB of the order on 20 nanometers, and a gate height of 120 nanometers, the duration of the first anneal is of the order of 10 minutes.

The nickel is incorporated in the silicon of the gate to obtain Ni₂Si (₂Ni+Si→Ni₂Si). Due to the diffusion, more nickel is incorporated at the gate edges because more nickel can be incorporated as nickel will diffuse from the insulating spacers, where it dies not react, toward the gate. However, in the centre of the gate, no excess nickel is available.

After a selective nickel removal, a second anneal in the temperature range of 350° C.-450° C. during 30 seconds up to two minutes is performed. Ni₂Si is transformed in NiSi. After this second thermal anneal a total silicidation of the gate down to the gate oxide at the edges of the gate is obtained as illustrated in FIG. 4, whereas doped polysilicon remains unreacted at the centre of the gate.

Thus, after this silicidation process, the bottom part of the gate comprises a central part PB1 (FIG. 4) comprises material A (here, doped polysilicon) and lateral parts PB2 formed with NiSi. The remaining part PU of the gate GR is also formed with NiSi.

Another implementation consists in using Co for the silicide formation inside the gate. Again the metal is deposited uniformly over the wafer comprising gate and spacers. The Co thickness is for example chosen between ⅙ and ¼ of the gate height. During a first thermal treatment at 530° C. during about one minute (gate height equal to 120 nm) the Cobalt reacts with the silicon Si to form CoSi. Again due to diffusion effects, more CoSi is formed at the gate edges. During a second anneal at around 830° C. during about one minute, CoSi reacts with the remaining Poly-Si to form the metal poor phase CoSi₂. The Co thickness has been chosen such that poly-Si remains unreacted in the central bottom part of the gate; thus there is again a midgap work function at the edges of the gate but not in the centre.

In view of the foregoing it will be evident to a person skilled in the art that various modifications may be made within the spirit and the scope of the invention as hereinafter defined by the appended claims and that the invention is thus not limited to the examples provided. In particular the words “comprise”, “include”, “incorporate”, “contain”, “is”, “have” do not exclude the presence of other elements or steps than those listed in a claim.

Further the reference signs in the claims do not limit the scope of the claims but are merely inserted to enhance the legibility of the claims.

1. Integrated circuit comprising at least one MOS transistor (T) including a gate (GR) having a bottom part in contact with the gate dielectric, said bottom part having an inhomogeneous work function (WF_{B}, WF_{A}) along the length of the gate between the source and drain regions, characterized by the fact that the gate comprises a first material (A) in a central area located at the centre of the bottom part of the gate in contact with said dielectric layer and a second material (B) in the remaining part of the gate.

2. Integrated circuit according to claim 1, wherein the value of the work function is greater at the extremities of the gate than in the centre of the gate if said MOS transistor is a NMOS transistor and smaller at the extremities of the gate than in the centre of the gate if said MOS transistor is a PMOS transistor.

3. Integrated circuit according to claim 1, wherein said first material (A) is N doped poly-silicon if said transistor is a NMOS transistor and P doped poly-silicon if said transistor is a PMOS transistor, and said second material (B) is a midgap material.

4. Integrated circuit according to claim 3, wherein said midgap material comprises a metal suicide.

5. Method of manufacturing a MOS transistor comprising:
forming a gate having a bottom part above and in contact with a dielectric layer, characterized by the fact that the gate forming phase comprises forming above said dielectric layer a gate region comprising a gate material;
forming insulating spacers on the lateral walls of the gate region;
forming a metal layer above said gate region; and
performing a transformation process including causing said metal layer to react with said gate material and choosing the thickness of said metal layer and process points of said transformation process such that at the end of the transformation process said gate region comprises a first material within a central area located at the centre of the bottom part of the gate region and a second material in the remaining part of said gate region, said second material having a work function different than the work function of said first material.

6. Method according to claim 5, wherein said second material has a work function greater than that of said first material if said MOS transistor is a NMOS transistor and smaller than that of said first material if said MOS transistor is a PMOS transistor.

7. Method according to claim 5, wherein all the gate material, except the portion thereof located within said central area, reacts with the metal layer during the transformation process so that said first material remains the gate material.

8. Method according to claim 5, wherein said gate material is a semiconductor gate material.

9. Method according to claim 5, wherein said transformation process is a silicidation process including thermal treatment, and choosing said process points of said transformation process comprises choosing the process points of said thermal treatment.

10. Method according to claim 9, wherein said gate material is N doped poly-silicon if said transistor is a NMOS transistor and P doped poly-silicon if said transistor is a PMOS transistor and said second material is metal suicide.

11. Method according to claim 10, wherein the thickness of said metal layer is smaller than the half of the thickness of the poly-silicon gate region.

12. Integrated circuit according to claim 2, wherein said first material (A) is N doped poly-silicon if said transistor is a NMOS transistor and P doped poly-silicon if said transistor is a PMOS transistor, and said second material (B) is a midgap material.

13. Method according to claim 6, wherein all the gate material, except the portion thereof located within said central area, reacts with the metal layer during the transformation process so that said first material remains the gate material.

14. Method according to claim 6, wherein said gate material is a semiconductor gate material.

15. Method according to claim 7, wherein said gate material is a semiconductor gate material.

16. Method according claims 6, wherein said transformation process is a silicidation process including thermal treatment, and choosing said process points of said transformation process comprises choosing the process points of said thermal treatment.

17. Method according claims 7, wherein said transformation process is a silicidation process including thermal treatment, and choosing said process points of said transformation process comprises choosing the process points of said thermal treatment.

18. Method according claims 8, wherein said transformation process is a silicidation process including thermal treatment, and choosing said process points of said transformation process comprises choosing the process points of said thermal treatment.

19. Method according to claim 16, wherein said gate material is N doped poly-silicon if said transistor is a NMOS transistor and P doped poly-silicon if said transistor is a PMOS transistor and said second material is metal suicide.

20. Method according to claim 17, wherein said gate material is N doped poly-silicon if said transistor is a NMOS transistor and P doped poly-silicon if said transistor is a PMOS transistor and said second material is metal suicide.
